(19) United States
(12) Patent Application Publication
(10) Pub. No.: US 2015/0021730 A1
(43) Pub. Date: Jan. 22, 2015

(54) CAMERA MODULE

(71) Applicant: HON HAI PRECISION INDUSTRY CO., LTD., New Taipei (TW)

(72) Inventor: SHIN-WEN CHEN, New Taipei (TW)

(21) Appl. No.: 14/335,948

(22) Filed: Jul. 21, 2014

(30) Foreign Application Priority Data
Jul. 19, 2013 (TW) 102126021

(51) Int. Cl. H01L 27/146

(52) U.S. Cl. CPC H01L 27/14627
USPC 257/432

(57) ABSTRACT

A camera module includes an image sensor, a packaging substrate, a lens holder, and a lens unit. The image sensor is positioned on a surface of the packaging substrate. The lens holder includes a base portion and a holding portion connected to the base portion. The base portion includes a number of protrusions protruding from a bottom surface thereof away from the holding portion. The lens holder is connected to the packaging substrate with the protrusions in contact with the packaging substrate. The lens unit is received in the lens holder and optical aligned with the image sensor.

### FIELD

The present disclosure relates to a camera module.

### BACKGROUND

A camera module generally includes a print circuit board (PCB), an image sensor positioned on the PCB, a lens holder covering the image sensor, and a lens connected to the lens holder. The lens holder is fixed to the PCB by an adhesive.

### BRIEF DESCRIPTION OF THE DRAWING

The components of the drawing are not necessarily drawn to scale, the emphasis instead being placed upon clearly illustrating the principles of the embodiments of the present disclosure.

FIG. 1 is an isometric, exploded view of an embodiment of a camera module of the present disclosure.

FIG. 2 is similar to FIG. 1, but showing the camera module from another angle.

FIG. 3 is an isometric view of the camera module of FIG. 1.

FIG. 4 is an enlarged view of circled portion IV of the camera module of

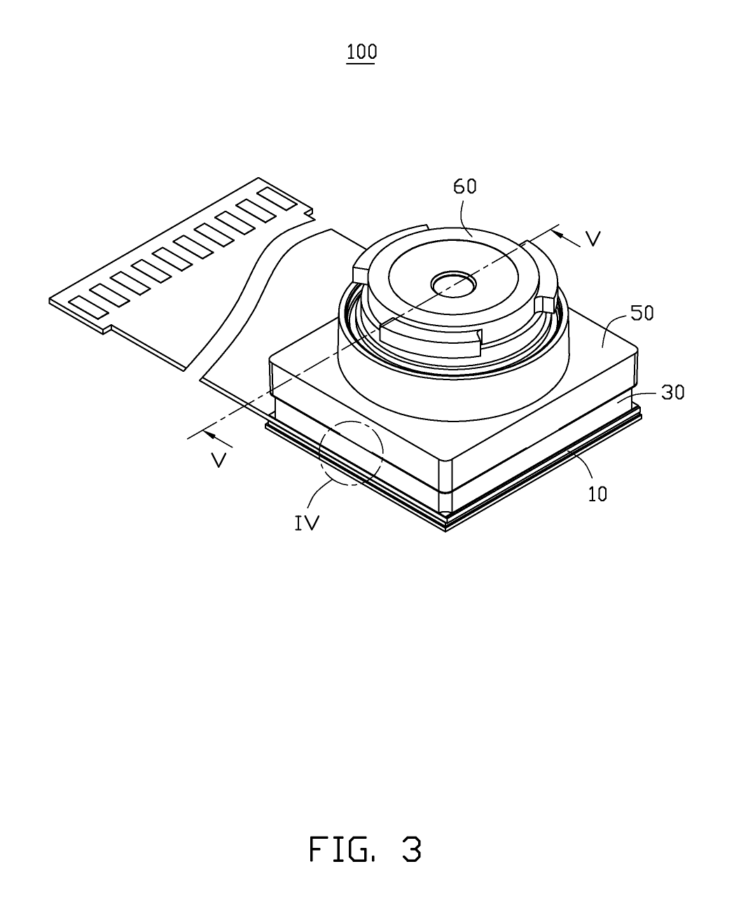

FIG. 3.

FIG. 5 is a cross-sectional view of the camera module of FIG. 3, taken along line V-V.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.” The references “a plurality of” and “a number of” mean “at least two.”

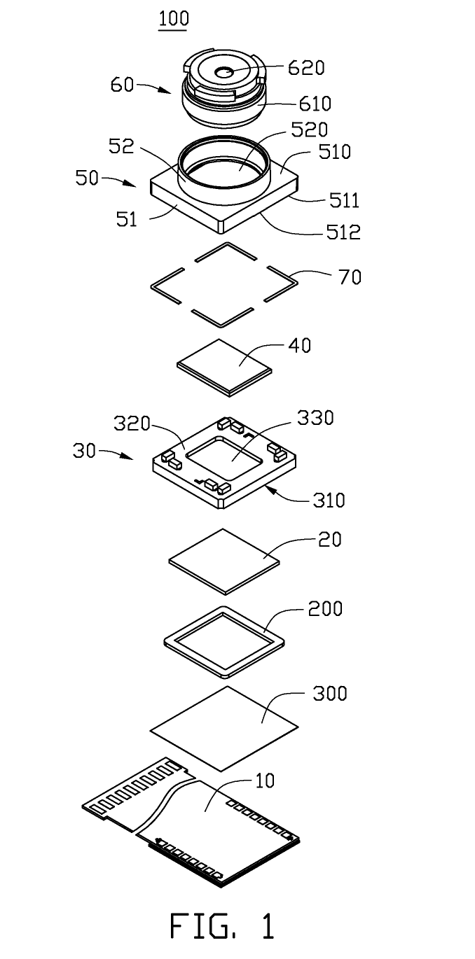

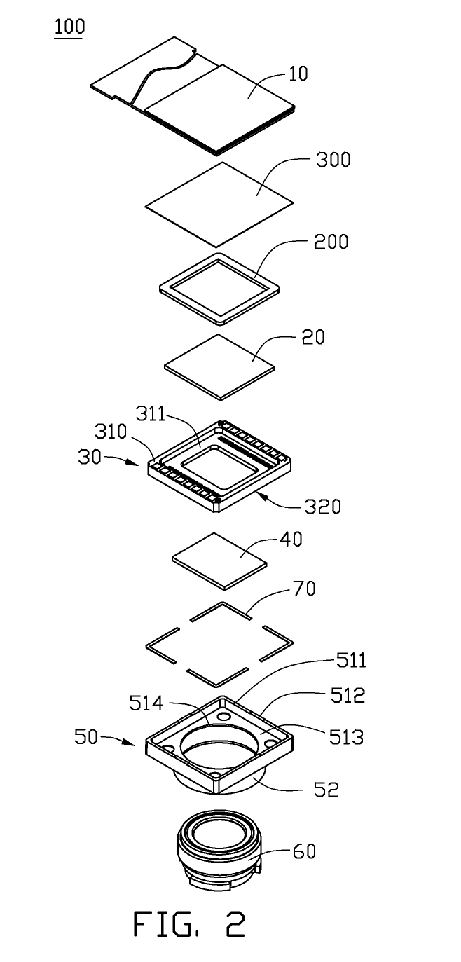

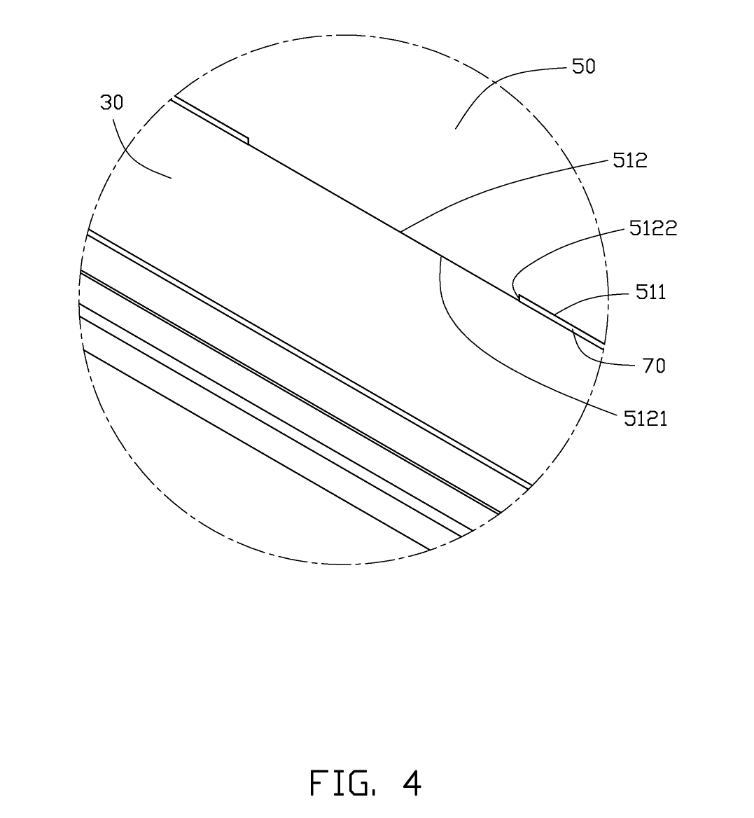

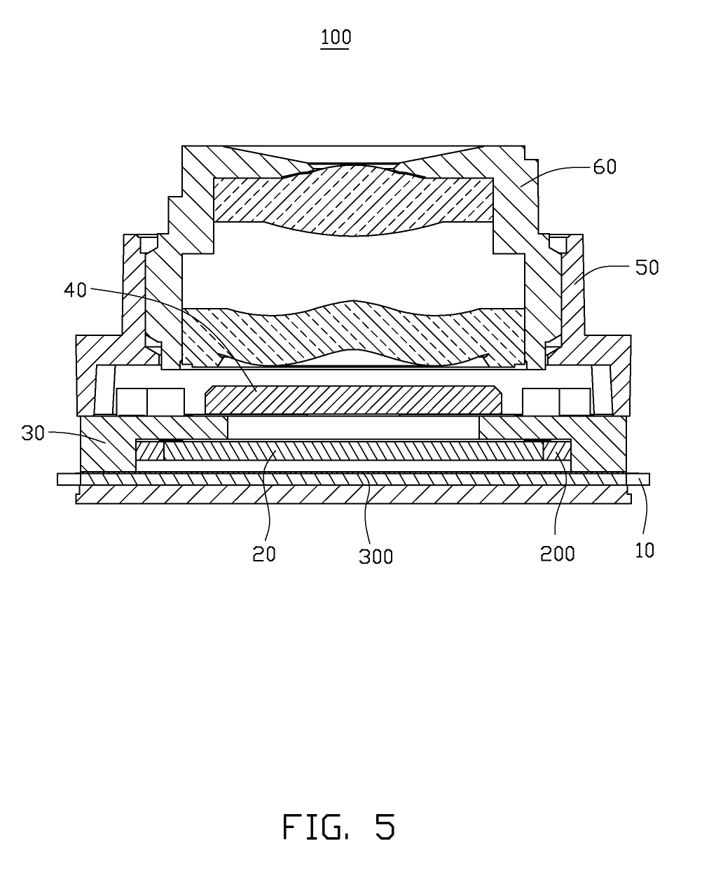

FIGS. 1-5 illustrate an embodiment of a camera module 100. The camera module 100 includes a printed circuit board (PCB) 10, an image sensor 20, a packaging substrate 30, an optical filter 40, a lens holder 50, and a lens unit 60. In this embodiment, the PCB 10 is a flexible PCB (FPCB).

The packaging substrate 30 is substantially rectangular-shaped. The packaging substrate 30 includes a first surface 310 facing toward the image sensor 20 and a second surface 320 opposite to the first surface 310. The packaging substrate 30 defines a receiving groove 311 in the first surface 310 and a through hole 330 passing through a bottom surface of the receiving groove 311 and the second surface 320. The receiving groove 311 is configured to receive the image sensor 20 therein. The through hole 330 allows light to pass therethrough and project on the image sensor 20. In this embodiment, the through hole 330 is substantially rectangular.

In this embodiment, the image sensor 20 is connected to the packaging substrate 30 by an adhesive 200. The adhesive 200 is distributed on peripheral sides of the image sensor 20. The packaging substrate 30 is connected to the PCB 10 by an anisotropic conductive film (ACF) 300.

The optical filter 40 is configured to filter light of predetermined wavelengths. In this embodiment, the optical filter 40 is an infrared-cut filter.

The lens holder 50 includes a base portion 51 and a holding portion 52 connected to the base portion 51. The base portion 51 is substantially rectangular. The base portion 51 includes a top surface 510 and a bottom surface 511 opposite to the top surface 510. The base portion 51 defines a receiving portion 513 in the bottom surface 511 and an opening 514 in the top surface 510. The receiving portion 513 is connected to the opening 514, and a size of the opening 514 is smaller than that of the receiving portion 513. In this embodiment, the receiving portion 513 is substantially rectangular, and the opening 514 is substantially circular. The base portion 51 includes a plurality of protrusions 512 protruding from the bottom surface 511. The protrusions 512 are spaced from each other and centrally and symmetrically arranged according to a central point of the bottom surface 511. In this embodiment, the number of the protrusions 512 is four, and each protrusion 512 is positioned at a side of the receiving portion 514. In alternative embodiments, the number of the protrusions 512 can be changed according to different requirements. Each protrusion 512 includes a contacting surface 5121 facing away from the bottom surface 511 and two opposite side surfaces 5122 connected to the contacting surface 5121 and the bottom surface 511. In this embodiment, the side surfaces 5122 are substantially parallel to each other. Alternatively, a predetermined angle can be formed between the side surfaces 5122, thus to make a cross section of the protrusion 512 to be substantially trapezoidal. In this embodiment, the side surfaces 5122 are roughened surfaces.

In this embodiment, the protrusions 512 are integrally formed with the bottom surface 511 of the base portion 51. The protrusions 512 and the base portion 51 each can be separately formed, then the protrusions 512 in fixed connected to the base portion 51.

The holding portion 52 is substantially cylindrical. The holding portion 52 defines an engaging hole 520 communicating with the opening 514 of the base portion 51.

The lens unit 60 includes a barrel 610 and two lenses 620 received in the barrel 610. In other embodiment, the number of the lenses 620 can be changed according to different requirements.

In assembly, the lens unit 60 engages the engaging hole 520 of the holding portion 52. The optical filter 40 is positioned on the second surface 320 of the packaging substrate 30 covering the through hole 330. An adhesive 70 is distributed on the bottom surface 511 of the base portion 51. The packaging substrate 30 is fixedly connected to the base portion 51 by the adhesive 70, and the contacting surface 5121 of each protrusion 512 is directly in contact with the second surface 320 of the packaging substrate 30. The roughened side surfaces 5122 can enhance adherence of the adhesive 70 between the packaging substrate 30 and the lens holder 50, thereby ensuring a connection stabilization between the packaging substrate 30 and the lens holder 50. The image sensor 20 is received in the receiving groove 311 of the packaging substrate 30 and is fixedly connected to an inner surface of the base portion 51 by the adhesive 200. The image sensor 20 is aligned with the lens unit 14 along an optical axis of the lens unit. The lens holder 50 with the lens unit 60, the packaging substrate 30, and the image sensor 20 are connected to the PCB 10 by the ACF 300. In detail, the lens holder 50 presses the ACF 300 toward the PCB 10 to adhere the first surface 310 of the packaging substrate 30 to the PCB 50, and the image sensor 20 is electrically connected to the PCB 10 by the ACF 300.

Generally, a pressing process for adhering the holder 50 to the PCB 100 by the ACF 300 should be under a relative high temperature and large pressing force, therefore, the adhesive 70 between the lens holder 50 and the package substrate 30 may by deformed by the temperature and the force during the pressing process. Because of the structure of the lens holder 50 with the protrusions 512 protruding from the bottom surface 511, the adhesive 70 can be distributed in an aperture between the packaging substrate 30 and the lens holder 50 spaced by the protrusions 512, the protrusions 512 can directly in contact with packaging substrate 30, therefore, the protrusions 512 can prevent a relative assembling distance between the lens unit 60 and the image sensor 20 from being changed by the pressing process, furthermore, the protrusions 512 can also prevent a sensing surface of the image senor 20 from tilting relative to an optical axis of the lens unit 60. Therefore, a precision assembly of the camera module 100 can be ensured.

Because the image sensor 20 and the lens unit 30 are aligned with each other by the lens holder 50 before the lens holder 50 is connected to the PCB 10, and the image sensor 20 does not directly contact with the PCB 10 in assembly of the camera module, the assembly of the camera module 100 can prevent misalignment between the lens unit 60 and the image sensor 20 in a process of connecting the lens holder 50 to the PCB 10.

It is believed that the present embodiments and their advantages will be understood from the foregoing description, and it will be apparent that various changes may be made thereto without departing from the scope of the disclosure or sacrificing all of its material advantages, the examples hereinbefore described merely being exemplary embodiments of the disclosure.

What is claimed is:

1. A camera module comprising:
an image sensor;
a packaging substrate having a surface configured to receive an image sensor;
a lens holder comprising a base portion and a holding portion connected to the base portion;
the base portion comprising a plurality of protrusions protruding from a bottom surface thereof in a direction away from the holding portion;
and the lens holder being connected to the packaging substrate with the protrusions directly in contact with the packaging substrate;, the lens holder and the packaging substrate being connected to each other by an adhesive distributed therebetween and
a lens unit received in the lens holder and optical aligned with the image sensor.

2. The camera module of claim 1, further comprising an optical filter positioned between the lens unit and the image sensor.

3. The camera module of claim 2, wherein the packaging substrate comprising a first surface facing toward the image sensor and a second surface opposite to the first surface, the packaging substrate defines a receiving groove in the first surface and a through hole passing through a bottom surface of the receiving groove and the second surface, the image sensor is received in the receiving groove, and the optical filter is positioned on the second surface covering the through hole.

4. The camera module of claim 3, wherein the image sensor is connected to an inner side surface of the base portion by an adhesive.

5. The camera module of claim 4, wherein the adhesive is distributed on peripheral sides of the image sensor.

6. The camera module of claim 1, wherein the packaging substrate is connected to the PCB 10 by an anisotropic conductive film.

7. The camera module of claim 1, wherein the base portion defines a receiving portion in the bottom surface and an opening in a surface opposite to the bottom surface, the receiving portion is communicated with the opening, and a size of the opening is smaller than that of the receiving portion.

8. The camera module of claim 1, wherein the protrusions are spaced form each other and centrally and symmetrically arranged according to a central point of the bottom surface.

9. The camera module of claim 1, wherein each protrusion comprises a contacting surface facing away from the bottom surface and two opposite side surfaces connected to the contacting surface and the bottom surface, the contacting surface is in contact with the packaging substrate.

10. The camera module of claim 9, wherein the adhesive is distributed on the bottom surface of the base portion and the side surfaces, the packing substrate is fixedly connected to the base portion by the adhesive.

11. The camera module of claim 10, wherein the side surfaces are roughened surfaces.
